(19) United States
(12) Patent Application Publication
(10) Pub. No.: US 2026/0150210 A1
(43) Pub. Date: May 28, 2026

(54) DISPLAY DEVICE

(71) Applicant: LG Display Co., Ltd., Seoul (KR)

(72) Inventor: Heechan Kim, Iksan-si (KR)

(73) Assignee: LG Display Co., Ltd., Seoul (KR)

(21) Appl. No.: 19/344,228

(22) Filed: Sep. 29, 2025

(30) Foreign Application Priority Data
Nov. 22, 2024 (KR) 10-2024-0168718

(51) Int. Cl. H05K 5/03

(52) U.S. Cl. CPC H05K 5/03

(57) ABSTRACT

A display device may include a display panel on which an image is displayed, a core plate disposed at a rear side of the display panel, a rear cover, a portion of which is disposed at the rear side of the core plate and configured to accommodate the core plate, and a rib disposed between the core plate and the rear cover and configured to distribute stress generated between the core plate and the rear cover due to a difference in deformation between the core plate and the rear cover.

### CROSS REFERENCE TO RELATED APPLICATION

The present application claims priority to Korean Patent Application No. 10-2024-0168718, filed Nov. 22, 2024, the entire contents of which is incorporated herein for all purposes by this reference.

### BACKGROUND

### Field

The present disclosure relates to a display device and, more particularly, to a display device having a structure with improved durability.

### Description of the Related Art

The content described in this section merely provides background information on the disclosure and does not constitute prior art.

As society enters the full-fledged information age, the field of display devices that visually represent electrical information signals has rapidly advanced, and research is ongoing to improve performance aspects such as reduced thickness, lighter weight, and lower power consumption for various types of display devices.

Examples of such display devices include Liquid Crystal Display (LCD) devices, Quantum Dot Display (QD) devices, Field Emission Display (FED) devices, Electro-Wetting Display (EWD) devices, and Organic Light Emitting Display (OLED) devices.

Display devices have been miniaturized to enhance portability for users or to be installed in mobile equipment, such as vehicles, thereby improving user convenience.

Furthermore, display devices have been continuously improved to increase screen resolution and brightness, providing clearer images to users.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

A display device may have a structure in which components made of different materials overlap one another. Such components of different materials may perform different functions within the display device.

For example, a metal component and a plastic component may be arranged to overlap each other, and the metal and plastic components may be fixedly coupled by a coupling mechanism such as a screw. However, where the metal component and the plastic component are joined by the coupling mechanism, stress caused by thermal expansion may become problematic.

When the display device operates, heat may be generated by the electricity applied to the display device, thereby heating the metal and plastic components.

In such cases, due to the difference in thermal expansion coefficients between the metal and plastic materials, thermal stress may be generated in the fixed metal and plastic components. Such stress caused by the difference in thermal expansion coefficients may degrade the durability of the respective components.

In particular, plastic components, which have relatively lower mechanical strength than metal, may experience deformation or breakage due to accumulated stress.

Additionally, thermal expansion of the plastic component may cause stress at the bonding area where the plastic component is adhered to another component. This is because deformation of the plastic component due to stress may cause stress concentration at specific regions of the bonding area located at an edge of the plastic component. Accordingly, deformation caused by stress in the plastic component may lead to deformation or damage of the bonding area.

Therefore, the stress caused by differences in thermal expansion coefficients of different materials should be properly distributed to prevent or reduce stress concentration in specific areas and thereby to suppress deformation or damage of display device components.

Accordingly, an object of the present disclosure is to provide a display device having a structure capable of distributing stress caused by differences in thermal expansion coefficients between components made of different materials.

Another object of the present disclosure is to provide a display device including a rib disposed between a core plate and a rear cover, the rib being configured to distribute stress generated due to differences in thermal expansion coefficients.

The objects of the present disclosure are not limited to those mentioned above, and other objects and advantages not explicitly stated will be understood from the following description and will become more apparent through example embodiments of the present disclosure. Moreover, it will be readily apparent that the objects and advantages of this specification can be realized by the means and combinations thereof set forth in the claims.

According to an example embodiment, a display device may include a display panel on which an image is displayed, a core plate disposed at a rear side of the display panel, a rear cover, a portion of which is disposed at the rear side of the core plate and configured to accommodate the core plate, and a rib disposed between the core plate and the rear cover and configured to distribute stress generated between the core plate and the rear cover due to a difference in deformation between the core plate and the rear cover.

The rib may be configured to move in position in response to deformation of the core plate and the rear cover, and to distribute stress occurring in at least one of the core plate and the rear cover.

According to another example embodiment, a display device may include a cover window, a display panel disposed at a rear side of the cover window and configured to display an image, a core plate disposed at a rear side of the display panel, a rear cover, a portion of which is disposed at a rear side of the core plate and configured to accommodate the core plate, an adhesive portion configured to bond edges of the cover window and the rear cover, and a rib disposed between the core plate and the rear cover and configured to distribute stress generated between the core plate and the rear cover due to a difference in deformation between the core plate and the rear cover.

The rib may include a first piece protruding from the core plate and having a first concave-convex portion formed at an end thereof, and a second piece protruding from the rear cover and having a second concave-convex portion formed at an end thereof, the second concave-convex portion having a shape corresponding to and engaging with the first concave-convex portion.

In the display device according to example embodiments of the present disclosure, it is possible to suppress stress from being concentrated in a specific narrow region among the regions where the core plate and the rear cover are joined by a rib.

Accordingly, when the core plate and the rear cover are heated, stress may be prevented or reduced from being concentrated on a portion of their coupling area or in a particular direction, and instead may be distributed throughout the rib, which is the coupling portion of the two components, and stress may also act simultaneously in intersecting directions.

As a result, it is possible to effectively suppress stress from being concentrated in a particular direction on a narrow region of the core plate and the rear cover due to heating, and thus to effectively prevent or reduce severe deformation or damage of the rear cover, which is formed of a relatively weaker plastic material, due to stress concentration.

Additionally, in the display device according to example embodiments of the present disclosure, since excessive deformation of the rear cover due to stress is suppressed by the rib, stress concentration at a specific portion of the adhesive portion located at the edge of the rear cover may also be suppressed.

Accordingly, deformation or damage of the adhesive portion due to stress concentration may be prevented or reduced, and damage to the cover window may be effectively suppressed.

Furthermore, in the display device according to example embodiments of the present disclosure, when the core plate and the rear cover are heated, their thermal expansion may become more pronounced at the corners. In particular, since the rear cover may have a thin bent portion at a corner, thermal expansion may become even more pronounced in this region.

Therefore, by disposing the rib at a corner of the core plate and the rear cover, stress concentration may be suppressed, and stress may be effectively distributed.

In addition to the aforementioned effects, other advantageous effects of the present disclosure will be provided along with the detailed description of the disclosure.

It is to be understood that both the foregoing general description and the following detailed description are by way of example and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain principles of the disclosure. In the drawings:

FIG. 1 is a perspective view illustrating a display device according to an example embodiment;

FIG. 2 is an exploded perspective view illustrating a display device according to an example embodiment;

FIG. 3 is a side view illustrating a display device according to an example embodiment;

FIG. 4 is a plan cross-sectional view illustrating a display device according to an example embodiment;

FIG. 5 is an enlarged view of a portion of FIG. 4;

FIG. 6 is a perspective view illustrating a rib according to an example embodiment;

FIG. 7 is a perspective view illustrating a first piece or a second piece according to an example embodiment;

FIG. 8 is a perspective view illustrating a first piece or a second piece according to another example embodiment;

FIG. 9 is a perspective view illustrating a example display device in a state where the rear cover is omitted;

FIG. 10 is an enlarged view of a portion of FIG. 9;

FIG. 11 is a front view illustrating a rear cover according to an example embodiment; and

FIG. 12 is an enlarged view of a portion of the rear cover according to an example embodiment.

### DETAILED DESCRIPTION

The aforementioned objectives, features, and advantages of the present disclosure will be described in detail with reference to the accompanying drawings, enabling those skilled in the art to easily implement the technical idea of the disclosure. Detailed descriptions of well-known technologies related to the present disclosure may be omitted where they may unnecessarily obscure features or aspects of the present disclosure. Hereinafter, example embodiments of the present disclosure will be described in detail with reference to the accompanying drawings. Identical reference numerals in the drawings are used to refer to identical or similar components.

Although terms such as ‘first,’ ‘second,’ and the like may be used to describe various components, these components are not limited by these terms. These terms are merely used to refer to one component separately from another, and unless explicitly stated otherwise, the first component may be the second component, and vice versa.

Throughout the specification, unless explicitly stated otherwise, each component may be singular or plural.

The singular expressions used in this specification include the plural expression, and vice versa, unless the context clearly indicates otherwise. In this application, terms such as ‘comprises’ or ‘includes’ should not be interpreted as necessarily including all the components or steps listed in the specification; some components or steps may be excluded, or additional components or steps may be included.

Throughout the specification, the term ‘A and/or B’ means A, B, or both A and B, unless otherwise stated, and the term ‘C to D’ means C or more and D or less, unless otherwise stated.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure.

Any implementation described herein as an “example” is not necessarily to be construed as preferred or advantageous over other implementations.

In addition, where any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even where a relevant description is not specified. Further, the term “may” fully encompasses all the meanings of the term “can.”

In the description of the various example embodiments of the present disclosure, where positional relationships are described, for example, where a position relation between two parts is described as, for example, “on,” “over,” “under,” and “next,” or the like, one or more other parts may be located between the two parts unless a more limiting term, such as “just” or “direct(ly)” is used. For example, where an element or layer is disposed “on” another element or layer, a third layer or element may be interposed therebetween.

In describing a temporal relationship, where the temporal order is described as, for example, “after,” “subsequent,” “next,” and “before,” a case that is not continuous may be included unless a more limiting term, such as “just,” “immediate(ly),” or “direct(ly)” is used.

Also, where an element or layer is described as “connected,” “coupled,” or “adhered” to another element or layer, the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements may be so disposed to directly contact each other, or may be so disposed without directly contacting each other.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It should be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in a co-dependent relationship.

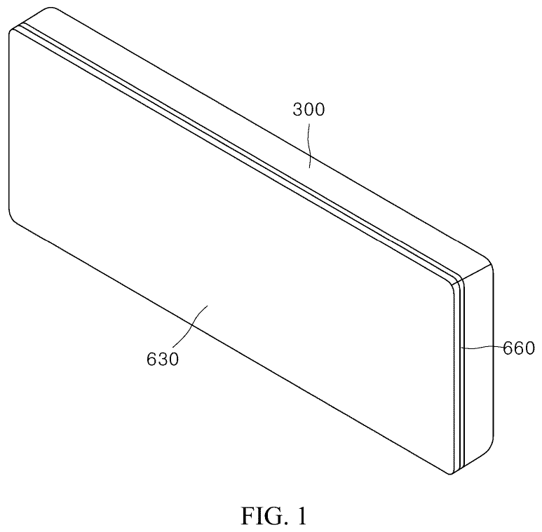

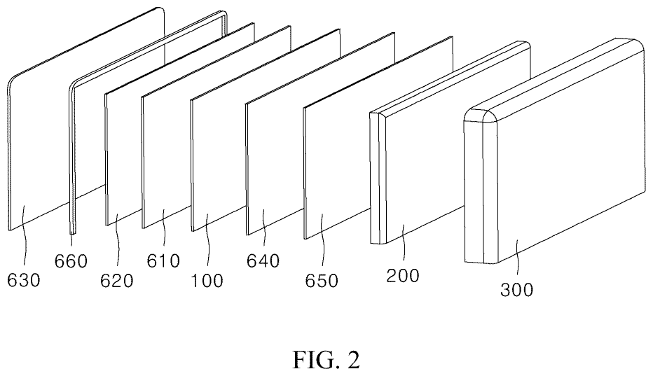

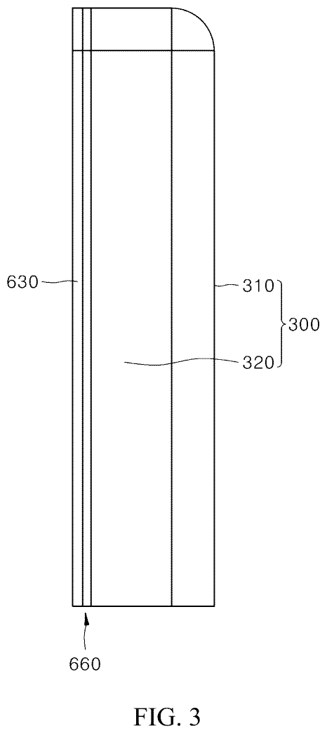

FIG. 1 is a perspective view illustrating a display device according to an example embodiment. FIG. 2 is an exploded perspective view illustrating a display device according to an example embodiment. FIG. 3 is a side view illustrating a display device according to an example embodiment.

As shown in FIG. 2, in this specification, “front” denotes the direction from the rear cover to the cover window, and the opposite direction is referred to as “rear.”

The display device according to an embodiment may be, for example, a vehicle display device mounted in front of the driver's seat in a vehicle.

The display device of an embodiment may include a display panel 100, a core plate 200, and a rear cover 300.

The display panel 100 may display images. In a vehicle display device, the displayed images may include navigation information for driving, video captured by cameras mounted in the vehicle, or various other content requested by the driver or passengers.

The core plate 200 may be disposed to the rear of the display panel 100. The core plate 200 may fix the display device of the embodiment to another object, such as a vehicle. The core plate 200 may be generally formed in a plate shape with a predetermined thickness and may be made of a metal material.

For example, the core plate 200 may be formed of magnesium and may be manufactured by a die-casting process.

The rear cover 300 may be partially disposed to the rear of the core plate 200 and may accommodate the core plate 200. The rear cover 300 may be coupled to the cover window 630 to form the outer appearance of the display device and may be adhered to the cover window 630 by the adhesive member 660.

An end portion of the rear cover 300 may be partially bent, thereby forming a space in which the core plate 200 is accommodated. For example, the rear cover 300 may be made of a plastic material and may be manufactured by an injection molding process.

That is, the cover window 630 and the rear cover 300 may be coupled to each other to form an internal space, and the core plate 200 and other components may be accommodated in this internal space.

The display device of the embodiment may include a polarizing plate 610, an adhesive layer 620, a cover window 630, a back plate 640, a metal plate 650, and an adhesive member 660.

The polarizing plate 610 may be disposed in front of the display panel 100. The polarizing plate 610 may convert light emitted from the display panel 100 into circularly polarized light. The polarizing plate 610 may improve outdoor visibility and contrast ratio of an image displayed on the display panel 100 by preventing or reducing reflection of external light.

The adhesive layer 620 may be disposed in front of the polarizing plate 610 and may bond the cover window 630 and the polarizing plate 610 to each other. The adhesive layer 620 may be made of a transparent material. For example, the adhesive layer 620 may be an optically clear adhesive (OCA) that is transparent and has a relatively low modulus.

The cover window 630 may be disposed in front of the adhesive layer 620. The cover window 630 may be adhered to the rear cover 300 to form the outer appearance of the display device and may protect other components of the display device.

The cover window 630 may be disposed at the very front of the display device. The cover window 630 may be positioned in front of the display panel 100 to protect the display panel 100. The cover window 630 may be formed of a transparent material such that light emitted from the display panel 100 may pass through the cover window 630.

The back plate 640 may be disposed to the rear of the display panel 100 and may support the display panel 100. The back plate 640 may include a light source that irradiates light to the display panel 100.

The metal plate 650 may be disposed to the rear of the back plate 640 and to the front of the core plate 200. The metal plate 650 may be formed to have a thin shape for manufacturing a slim-type display device.

The metal plate 650 may protect the display panel 100 and the back plate 640 and may serve as a heat sink by dissipating heat generated from the display panel 100 and the back plate 640 to the outside to cool the display panel 100 and the back plate 640.

The metal plate 650 may be made of, for example, aluminum or an alloy including aluminum.

The adhesive member 660 may be disposed between the cover window 630 and the rear cover 300. The adhesive member 660 may bond the edges of the cover window 630 and the rear cover 300 to each other.

The adhesive member 660 may have a generally U-shaped form and may be adhered to the bent portion at the edge of the rear cover 300. By the adhesive member 660, the cover window 630 and the rear cover 300 may be bonded to each other at their edges.

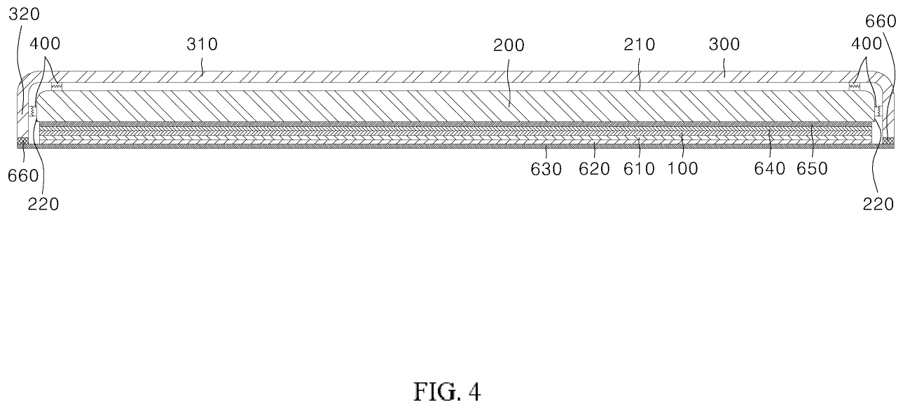

FIG. 4 is a plan cross-sectional view illustrating a display device according to an example embodiment.

The core plate 200, which is a structure for mounting the display device to a vehicle, needs to be stably coupled with other components of the display device. Due to this structure, the display device mounted to a vehicle by the core plate 200 may maintain its position even when subjected to external impact and may provide a stable image to the user without shaking.

To this end, the core plate 200 may be fixedly coupled to the rear cover 300. For example, the core plate 200 and the rear cover 300 may be coupled by a coupling mechanism such as a screw. However, in such a case, stress caused by thermal expansion of each component may become an issue.

When the display device is operating, heat may be generated by the electricity applied to the display device, and accordingly, the core plate 200 made of a metal material and the rear cover 300 made of a plastic material may be heated.

In such a case, due to the difference in thermal expansion coefficients between the metal and the plastic, stress due to thermal expansion may occur in the core plate 200 and the rear cover 300 that are fixed to each other. The stress applied to the core plate 200 and the rear cover 300 due to the difference in thermal expansion coefficients may reduce the durability of each component.

In particular, the rear cover 300 made of plastic, which has relatively lower mechanical strength than metal, may experience deformation or breakage due to the accumulation of such stress.

In addition, thermal expansion of the rear cover 300 may generate stress in the adhesive member 660 that bonds the rear cover 300 to the cover window 630. This is because deformation of the rear cover 300 due to stress may cause stress to be concentrated on a specific portion of the adhesive member 660 located at the edge of the rear cover 300. Accordingly, deformation of the rear cover 300 due to stress may cause deformation or breakage of the adhesive member 660.

Furthermore, the concentrated stress on the adhesive member 660 may lead to damage of the cover window 630 to which the adhesive member 660 is bonded.

Therefore, the stress caused by differences in thermal expansion coefficients of different materials should be properly distributed to prevent or reduce stress concentration in specific areas and thereby to suppress deformation or damage of display device components.

In an embodiment, the above-described problems may be resolved by coupling the rear cover 300 and the core plate 200 and disposing a rib 400 between the rear cover 300 and the core plate 200 to disperse stress applied thereto. Hereinafter, the rib 400 will be described in detail with reference to the drawings.

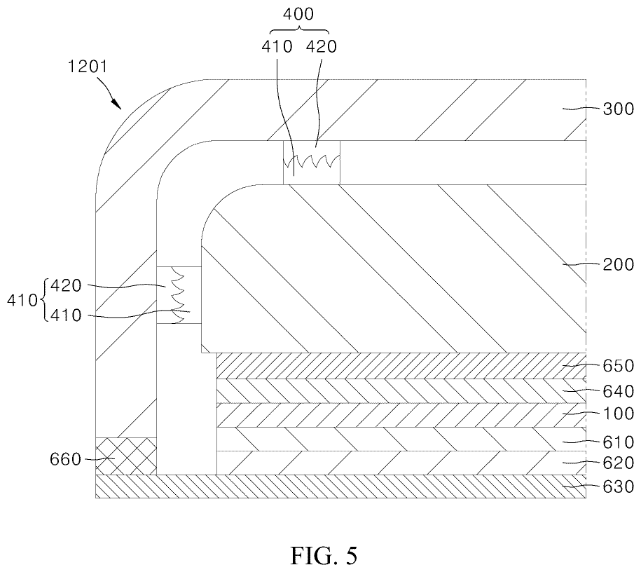

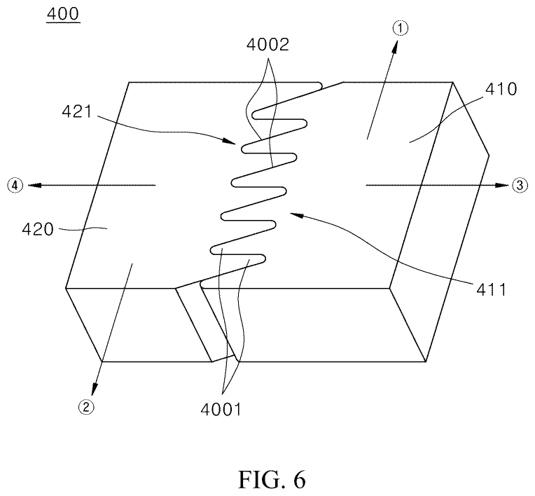

FIG. 5 is an enlarged view of a portion of FIG. 4. FIG. 6 is a perspective view illustrating the rib 400 according to an example embodiment. The display device of this embodiment may include a rib 400.

The rib 400 may be disposed between the core plate 200 and the rear cover 300, and may disperse stress generated in the core plate 200 and the rear cover 300 due to a difference in deformation between the core plate 200 and the rear cover 300.

The rib 400 may disperse the stress generated in the core plate 200 and the rear cover 300 due to the difference in deformation caused by the material difference between the core plate 200 and the rear cover 300 when the display device operates and heats up.

The rib 400 may move in position according to the deformation of the core plate 200 and the rear cover 300, thereby dispersing the stress generated in at least one of the core plate 200 or the rear cover 300.

The rib 400 may include a first piece 410 and a second piece 420. The first piece 410 may protrude from the core plate 200 and have a first concave-convex portion 411 formed at its end. The second piece 420 may protrude from the rear cover 300 and have a second concave-convex portion 421 formed at its end, the shape of which corresponds to and interlocks with the first concave-convex portion 411.

The first concave-convex portion 411 and the second concave-convex portion 421 may include a recess 4001 having at least one inclined surface 4002. The first concave-convex portion 411 and the second concave-convex portion 421 may be generally formed in a sawtooth shape and may interlock with each other.

By the interlocking engagement between the first concave-convex portion 411 and the second concave-convex portion 421, the first piece 410 and the second piece 420 may be coupled to each other, whereby the core plate 200 and the rear cover 300 may also be coupled together. Of course, as will be described later, the core plate 200 and the rear cover 300 may additionally be coupled by a coupling mechanism.

Since the first concave-convex portion 411 and the second concave-convex portion 421 are provided in corresponding sawtooth shapes, the first piece 410 and the second piece 420 may easily interlock with each other during an assembly process of coupling the core plate 200 and the rear cover 300, which may facilitate the assembly of the display device.

The description will now be made with reference to FIG. 6. Due to the difference in coefficients of thermal expansion, stress may be applied to the first piece 410 of the rib 400 in the direction \textcircled{1}, and to the second piece 420 in the direction \textcircled{2}. This is because the core plate 200 made of metal and the rear cover 300 made of plastic have different coefficients of thermal expansion, resulting in different elongations, which may cause stress to be generated in opposite directions.

Of course, stress may also be generated in the core plate 200 and the rear cover 300 in the same directions as the directions in which stress is applied to the first piece 410 and the second piece 420.

In this case, the first concave-convex portion 411 of the first piece 410 and the second concave-convex portion 421 of the second piece 420 may be formed with inclined surfaces 4002, and due to the inclined surfaces 4002, a portion of the stress applied to the first piece 410 and the second piece 420 may be applied in directions \textcircled{3} and \textcircled{4}, which intersect directions \textcircled{1} and \textcircled{2}.

That is, a portion of the stress in the first piece 410 and the second piece 420 may be dispersed in directions \textcircled{3} and \textcircled{4}. Accordingly, the stress may be dispersed in intersecting directions within the first piece 410 and the second piece 420.

Due to such a structure, compared to the case where stress is applied only in directions \textcircled{1} and \textcircled{2}, it may be possible to suppress stress from being concentrated in a specific region and direction of each of the core plate 200 and the rear cover 300.

That is, even among the regions where the rib 400 for coupling the core plate 200 and the rear cover 300 is formed, stress concentration in a narrower specific portion may be suppressed.

Accordingly, when the core plate 200 and the rear cover 300 are heated, stress may be prevented or reduced from being concentrated in a particular direction and region of their coupling area, and the stress may be dispersed across the entire rib 400, which serves as the coupling portion, while simultaneously acting in intersecting directions.

As a result, stress concentration in a narrow specific region of the core plate 200 and the rear cover 300 in a particular direction due to heating may be effectively suppressed, and thus, severe deformation or damage to the rear cover 300, which is relatively weaker due to being formed of plastic, may be effectively prevented or reduced.

Additionally, since the rib 400 suppresses excessive deformation of the rear cover 300 caused by stress, stress concentration on a specific region of the adhesive member 660 at the edge of the rear cover 300 may also be suppressed.

Accordingly, deformation or damage of the adhesive member 660 caused by stress concentration may be prevented or reduced, and damage to the cover window 630 may be effectively suppressed.

The first piece 410 may be integrally formed with the core plate 200, and the second piece 420 may be integrally formed with the rear cover 300.

When the core plate 200 and the first piece 410 are separately manufactured and then assembled together, there may be a risk of separation or damage at the coupling portion due to repeated thermal expansion. Accordingly, the core plate 200 and the first piece 410 may be integrally formed to improve the durability of the display device.

For the same reason, it may also be appropriate to integrally form the rear cover 300 and the second piece 420.

The core plate 200 and the first piece 410, which are made of metal, may be integrally formed by, for example, a die casting method. The rear cover 300 and the second piece 420, which are made of plastic, may be integrally formed by an injection molding method.

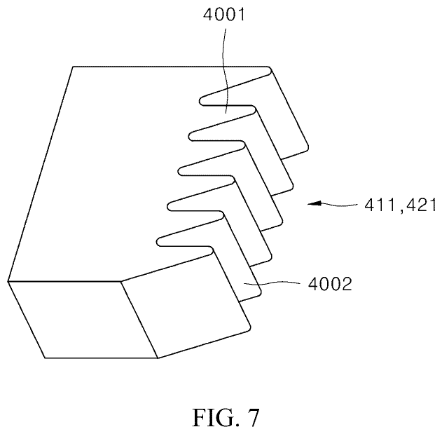

FIG. 7 is a perspective view illustrating the first piece 410 or the second piece 420 according to an embodiment. In an embodiment, the recess 4001 of the first piece 410 or the second piece 420 may be formed in an asymmetric shape having two surfaces with different inclination angles.

As shown in FIG. 7, for example, one surface of the recess 4001 may be formed as an inclined surface 4002 having a slope, and the other surface of the recess 4001 may be formed as a surface substantially perpendicular to directions \textcircled{1} and \textcircled{2}, such that the two surfaces of the recess 4001 may have different inclinations.

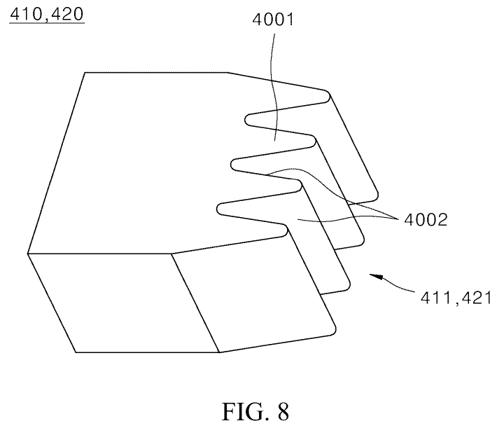

FIG. 8 is a perspective view illustrating the first piece 410 or the second piece 420 according to another example embodiment. In another embodiment, the recess 4001 of the first piece 410 or the second piece 420 may be formed in a symmetric shape having two inclined surfaces 4002 with the same inclination angle.

Even when the inclined surface 4002 is formed only on one side of the recess 4001, the stress may be dispersed in directions \textcircled{3} and \textcircled{4}, and thus one side of the recess 4001 may be formed as a right-angled surface while the other side is formed as the inclined surface 4002.

The formation of the recess 4001 may be designed to reflect the size, specific structure, and thermal deformation characteristics of the display device. That is, the rib 400 may be designed by appropriately adjusting the number and size of the recesses 4001 of the first piece 410 and the second piece 420, as well as the angles of the inclined surfaces 4002, in consideration of the size, structure, and thermal deformation characteristics according to the material of each component of the display device.

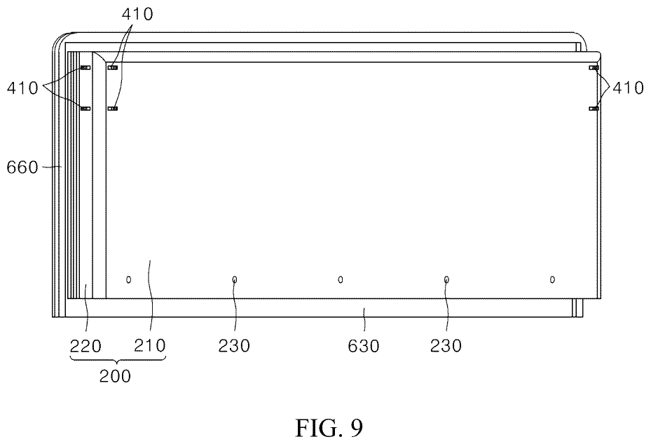

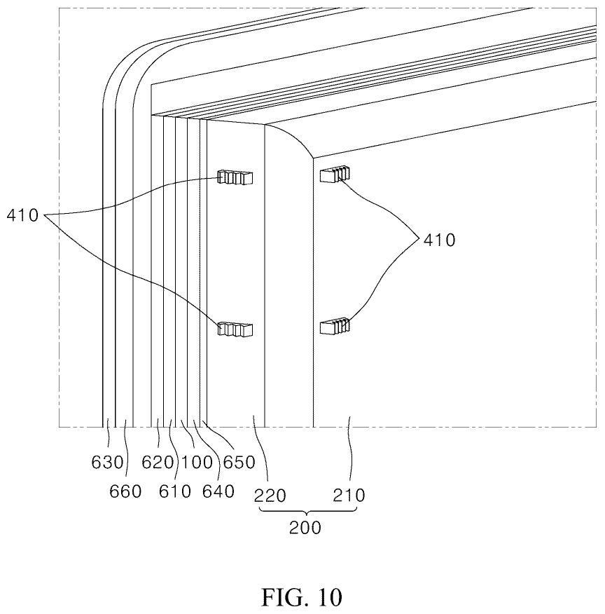

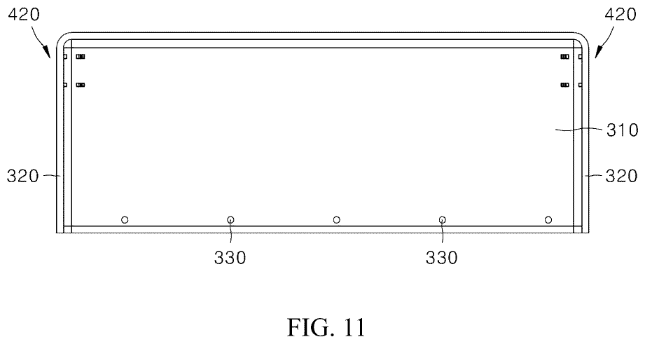

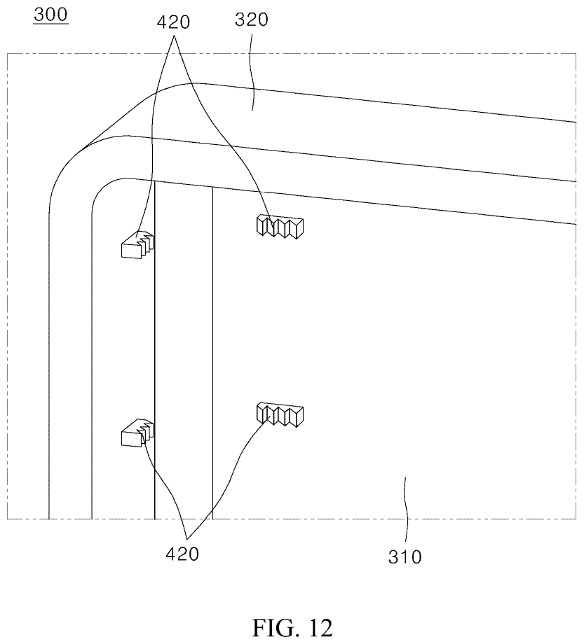

FIG. 9 is a perspective view illustrating an example display device in a state where the rear cover 300 is omitted. FIG. 10 is an enlarged view of a portion of FIG. 9. FIG. 11 is a front view illustrating the rear cover 300 according to an example embodiment. FIG. 12 is an enlarged view of a portion of the rear cover 300 according to an example embodiment.

The rib 400 may be arranged to be positioned at the edges 1201 of the core plate 200 and the corresponding edges 1201 of the rear cover 300.

When the core plate 200 and rear cover 300 are heated, their thermal expansion may become more pronounced at the edges 1201. In particular, the rear cover 300 may have a thin bent section at the edges 1201, making thermal expansion more significant in this area.

Therefore, by placing the rib 400 at the edges 1201 of the core plate 200 and rear cover 300, stress concentration can be suppressed, and stress can be effectively distributed.

In one embodiment, the core plate 200 may include a first planar portion 210 and a side portion 220 defined by both sides of the first planar portion 210. The first piece 410 may be positioned on both the first planar portion 210 and the side portion 220.

At least one first piece 410 may be positioned on the first planar portion 210 and the side portion 220. For broader stress distribution, it is preferable to have a plurality of first pieces 410 arranged on both the first planar portion 210 and the side portion 220.

Meanwhile, the second piece 420 of the rear cover 300 may be provided in a quantity corresponding to the first piece 410 of the core plate 200.

The rear cover 300 may include a second planar portion 310 and a bent portion 320 bent from the second planar portion 310. The second piece 420 may be positioned on both the second planar portion 310 and the bent portion 320. The position and number of the second pieces 420 arranged on the second planar portion 310 and the bent portion 320 may correspond to the position and number of the first pieces 410.

That is, the rib 400 may be arranged on different surfaces of the core plate 200 and rear cover 300, respectively. Due to this structure, stress can be distributed over a wide range at the edges 1201 of the core plate 200 and the rear cover 300.

The number of ribs 400 arranged on each surface of the edges 1201 of the core plate 200 and rear cover 300 may be appropriately set, considering factors such as the size, structure, and thermal deformation characteristics of each component of the display device.

In addition to the ribs 400, the core plate 200 and rear cover 300 may be further coupled by coupling mechanisms such as screws to maintain a stable connection.

However, when the core plate 200 and rear cover 300 are fixedly coupled by the coupling mechanisms, stress may arise at the coupling point due to the difference in thermal expansion rates between the materials of the core plate 200 and rear cover 300.

Therefore, the coupling point by the coupling mechanism needs to be positioned in a location where the stress caused by heat in the core plate 200 and rear cover 300 will not cause deformation of these parts. Considering these factors, the following describes the position where the core plate 200 and rear cover 300 are fixedly coupled by the coupling mechanism in the embodiment.

The core plate 200 may include a plurality of first fastening holes 230 that are spaced apart on the first planar portion 210, for securing the coupling mechanism.

As shown in FIG. 9, the first fastening holes 230 may be arranged as a plurality on the first planar portion 210 of the core plate 200 in a direction parallel to the lateral direction of the display device.

Correspondingly, the rear cover 300 may include a plurality of second fastening holes 330, each formed at positions corresponding to the first fastening holes 230 on the second planar portion 310, to secure the coupling mechanism.

As shown in FIG. 11, the second fastening holes 330 may be arranged as a plurality on the second planar portion 310 of the rear cover 300 in a direction parallel to the lateral direction of the display device. The second fastening holes 330 may be formed at positions corresponding to the first fastening holes 230 of the core plate 200, with the number of second fastening holes 330 corresponding to the number of first fastening holes 230.

As mentioned earlier, stress caused by thermal expansion in the core plate 200 and rear cover 300 is particularly noticeable at the edges 1201. Therefore, the edges 1201 of the core plate 200 and rear cover 300 may be coupled using ribs 400, effectively suppressing deformation and damage caused by stress.

Additionally, fastening holes may be formed at the planar portions of the core plate 200 and rear cover 300, where stress generation is not relatively significant, allowing the core plate 200 and rear cover 300 to be coupled together using the coupling mechanism.

By using the coupling mechanism at locations where stress is not significant, the core plate 200 and rear cover 300 can be coupled in a stable and secure manner, without causing deformation or damage due to stress.

As shown in FIGS. 9 and 10, the first fastening holes 230 and the second fastening holes 330 are not formed on the side portions 220 of the core plate 200 and the bent portions 320 of the rear cover 300, but may be formed on the planar portions spaced apart by a predetermined distance from the side portions 220 and the bent portions 320.

This structure helps reduce the magnitude of the stresses caused by the coupling mechanism on the side portions 220 and bent portions 320, where stress due to thermal expansion is significant, thereby significantly reducing the deformation and damage of the core plate 200 and rear cover 300 caused by stress.

The first piece 410 and the second piece 420 may be arranged on one side of the core plate 200 and rear cover 300. On the other hand, the first fastening holes 230 and the second fastening holes 330 may be arranged on the opposite sides of the core plate 200 and rear cover 300, respectively.

As illustrated in FIGS. 9 and 10, when the display device is mounted in a vehicle, the rib 400 is arranged at the upper corners (e.g., edges 1201) on both sides of the display device, and the coupling mechanism securing the fastening holes may be arranged on the lower planar portion of the display device.

Thus, the rib 400 and the coupling mechanism may be arranged at significantly separated positions in the vertical direction of the display device. As a result, the stress generated at the fastening mechanism does not affect or has little effect on the rib 400.

Therefore, the stress generated by the fastening mechanism does not impact the upper corners of the display device, and accordingly, deformation and damage of the rear cover 300 due to stress at these corners can be effectively prevented or reduced.

A display device according to an example embodiment includes a display panel configured to display an image, a core plate disposed behind the display panel, a rear cover partially disposed behind the core plate and configured to accommodate the core plate, and a rib disposed between the core plate and the rear cover and configured to disperse stress in the core plate and the rear cover caused by a difference in deformation therebetween.

The rib may move, in response to deformation of the core plate and the rear cover, to disperse stress in at least one of the core plate or the rear cover.

The rib may include a first piece protruding from the core plate and having a first concave-convex portion at an end thereof, and a second piece protruding from the rear cover and having a second concave-convex portion at an end thereof, the second concave-convex portion corresponding in shape to and engaging with the first concave-convex portion.

The first piece may be integrally formed with the core plate, and the second piece may be integrally formed with the rear cover.

The first concave-convex portion and the second concave-convex portion each may include a recess having at least one inclined surface.

The recess may be symmetrically formed with two inclined surfaces having a same inclination angle.

The recess may be asymmetrically formed with two surfaces having different inclination angles.

The rib may be disposed at a corner of the core plate and a corresponding corner of the rear cover.

The core plate may include a first planar portion and side portions defined by surfaces on both sides of the first planar portion, and the first piece may be disposed on each of the first planar portion and the side portions.

The rear cover may include a second planar portion and a bent portion bent from the second planar portion, and the second piece may be disposed on each of the second planar portion and the bent portion.

The core plate may include a plurality of first fastening holes spaced apart on the first planar portion for fastening a coupling mechanism, and the rear cover may include a plurality of second fastening holes formed on the second planar portion at positions corresponding to the first fastening holes for fastening the coupling mechanism.

The first piece and the second piece may be disposed on one side of the core plate and the rear cover, respectively, and the first fastening holes and the second fastening holes may be disposed on an opposite side of the core plate and the rear cover, respectively.

A display device according to an example embodiment may further include a polarizing plate disposed in front of the display panel, an adhesive layer disposed in front of the polarizing plate, a cover window disposed in front of the adhesive layer, a back plate disposed behind the display panel and configured to support the display panel, and a metal plate disposed behind the back plate and in front of the core plate.

A display device according to an example embodiment may further include an adhesive member configured to bond an edge of the cover window to an edge of the rear cover.

A display device according to another example embodiment may include a cover window, a display panel disposed behind the cover window and configured to display an image, a core plate disposed behind the display panel, a rear cover partially disposed behind the core plate and configured to accommodate the core plate, an adhesive member configured to bond an edge of the cover window to an edge of the rear cover, and a rib disposed between the core plate and the rear cover and configured to disperse stress in the core plate and the rear cover caused by a difference in deformation therebetween.

The rib may include a first piece protruding from the core plate and having a first concave-convex portion at an end thereof, and a second piece protruding from the rear cover and having a second concave-convex portion at an end thereof, the second concave-convex portion corresponding in shape to and engaging with the first concave-convex portion.

The first concave-convex portion and the second concave-convex portion each may include a recess having at least one inclined surface.

The rib may be disposed at a corner of the core plate and a corresponding corner of the rear cover, the core plate may include a first planar portion and side portions defined by surfaces on both sides of the first planar portion, the first piece being disposed on each of the first planar portion and the side portions, and the rear cover may include a second planar portion and a bent portion bent from the second planar portion, the second piece being disposed on each of the second planar portion and the bent portion.

The core plate may include a plurality of first fastening holes spaced apart on the first planar portion for fastening a coupling mechanism, and the rear cover may include a plurality of second fastening holes formed on the second planar portion at positions corresponding to the first fastening holes for fastening the coupling mechanism.

While the present disclosure has been described above with reference to example embodiments and drawings, it is not limited to the example embodiments and drawings disclosed in this specification, and it will be apparent to those skilled in the art that various modifications may be made without departing from the scope of the technical idea of the disclosure. Furthermore, even if the operational effects according to various configurations of the present disclosure are not explicitly described in the explanation of the example embodiments, the predictable effects resulting from the corresponding configurations should naturally be recognized as well.

What is claimed is:

1. A display device, comprising:
a display panel configured to display an image;
a core plate disposed behind the display panel;
a rear cover partially disposed behind the core plate and configured to accommodate the core plate; and
a rib disposed between the core plate and the rear cover and configured to disperse stress in the core plate and the rear cover caused by a difference in deformation between the core plate and the rear cover.

2. The display device of claim 1, wherein the rib moves in response to deformation of the core plate and the rear cover to disperse stress in at least one of the core plate or the rear cover.

3. The display device of claim 1, wherein the rib comprises:
a first piece protruding from the core plate and having a first concave-convex portion at an end of the first piece; and
a second piece protruding from the rear cover and having a second concave-convex portion at an end of the second piece, the second concave-convex portion corresponding in shape to and engaging with the first concave-convex portion.

4. The display device of claim 3, wherein the first piece is integrally formed with the core plate, and the second piece is integrally formed with the rear cover.

5. The display device of claim 3, wherein the first concave-convex portion and the second concave-convex portion each include a recess having at least one inclined surface.

6. The display device of claim 5, wherein the recess is symmetrically formed with two inclined surfaces having a same inclination angle.

7. The display device of claim 5, wherein the recess is asymmetrically formed with two surfaces having different inclination angles.

8. The display device of claim 3, wherein the rib is disposed at a corner of the core plate and a corresponding corner of the rear cover.

9. The display device of claim 3, wherein the core plate comprises a first planar portion and side portions defined by surfaces on both sides of the first planar portion, and the first piece is disposed on each of the first planar portion and the side portions.

10. The display device of claim 9, wherein the rear cover comprises a second planar portion and a bent portion bent from the second planar portion, and the second piece is disposed on each of the second planar portion and the bent portion.

11. The display device of claim 10, wherein the core plate comprises a plurality of first fastening holes spaced apart on the first planar portion for fastening a coupling mechanism, and the rear cover comprises a plurality of second fastening holes formed on the second planar portion at positions corresponding to the first fastening holes for fastening the coupling mechanism.

12. The display device of claim 11, wherein the first piece and the second piece are disposed on one side of the core plate and the rear cover, respectively, and the first fastening holes and the second fastening holes are disposed on an opposite side of the core plate and the rear cover, respectively.

13. The display device of claim 1, further comprising:
a polarizing plate disposed in front of the display panel;
an adhesive layer disposed in front of the polarizing plate;
a cover window disposed in front of the adhesive layer;
a back plate disposed behind the display panel and configured to support the display panel; and
a metal plate disposed behind the back plate and in front of the core plate.

14. The display device of claim 13, further comprising an adhesive member configured to bond an edge of the cover window to an edge of the rear cover.

15. A display device, comprising:
a cover window;
a display panel disposed behind the cover window and configured to display an image;
a core plate disposed behind the display panel;
a rear cover partially disposed behind the core plate and configured to accommodate the core plate;
an adhesive member configured to bond an edge of the cover window to an edge of the rear cover; and
a rib disposed between the core plate and the rear cover and configured to disperse stress in the core plate and the rear cover caused by a difference in deformation between the core plate and the rear cover.

16. The display device of claim 15, wherein the rib comprises:
a first piece protruding from the core plate and having a first concave-convex portion at an end of the first piece; and
a second piece protruding from the rear cover and having a second concave-convex portion at an end of the second piece, the second concave-convex portion corresponding in shape to and engaging with the first concave-convex portion.

17. The display device of claim 16, wherein the first concave-convex portion and the second concave-convex portion each include a recess having at least one inclined surface.

18. The display device of claim 16, wherein the rib is disposed at a corner of the core plate and a corresponding corner of the rear cover, the core plate comprises a first planar portion and side portions defined by surfaces on both sides of the first planar portion, the first piece being disposed on each of the first planar portion and the side portions, and the rear cover comprises a second planar portion and a bent portion bent from the second planar portion, the second piece being disposed on each of the second planar portion and the bent portion.

19. The display device of claim 18, wherein the core plate comprises a plurality of first fastening holes spaced apart on the first planar portion for fastening a coupling mechanism, and the rear cover comprises a plurality of second fastening holes formed on the second planar portion at positions corresponding to the first fastening holes for fastening the coupling mechanism.
